(19) United States
(12) Patent Application Publication
(10) Pub. No.: US 2020/0144205 A1
(43) Pub. Date: May 7, 2020

(54) SEMICONDUCTOR DEVICE, SEMICONDUCTOR DEVICE ASSEMBLY AND METHOD FOR MANUFACTURING SEMICONDUCTOR DEVICE ASSEMBLY

(71) Applicant: NANYA TECHNOLOGY CORPORATION, New Taipei City (TW)

(72) Inventor: Chien-Chung WANG, New Taipei City (TW)

(21) Appl. No.: 16/183,405

(22) Filed: Nov. 7, 2018

(51) Int. Cl. H01L 23/58; H01L 21/78; H01L 23/535; H01L 29/94

(52) U.S. Cl. CPC H01L 23/585; H01L 21/78; H01L 23/481; H01L 29/945; H01L 23/535

(57) ABSTRACT

The present disclosure provides a semiconductor device, a semiconductor device assembly, and a method for manufacturing the semiconductor device assembly. The semiconductor device includes a wafer, a semiconductor chip, and a plurality of first reinforced structures. The semiconductor chip is disposed on the wafer and has a non-functional region and at least one functional region disposed in the non-functional region. The first reinforced structures located in the non-functional region penetrate through the semiconductor chip and into the wafer.

### TECHNICAL FIELD

The present disclosure relates to a semiconductor device, a semiconductor device assembly and a method for manufacturing the semiconductor device assembly, and more particularly, to a semiconductor device and a semiconductor device assembly with m reinforced structures and a method for manufacturing the semiconductor device assembly.

### DISCUSSION OF THE BACKGROUND

As semiconductor devices, such as memory devices, are becoming increasingly integrated, achieved degree of integration with typical two-dimensional (2D) structures is rapidly approaching its limit. Therefore, there is a need for a semiconductor memory device having a three-dimensional (3D) structure that exceeds the 2D structure in integration capability. Such need has led to extensive research into developing 3D semiconductor memory device technology.

In a 3D semiconductor memory device, various signals carrying data, commands, or addresses are transmitted, some or all of which are transmitted through a through silicon via (TSV). The through silicon via is a structure formed through stacked films and a wafer carrying the stacked films. In general, the wafer is ground to reduce its size; however, the ground wafer may warp during a sawing process. As a result of the warpage of the wafer, the connection of semiconductor memory devices through the through silicon via may fail.

This Discussion of the Background section is provided for background information only. The statements in this Discussion of the Background are not an admission that the subject matter disclosed in this Discussion of the Background section constitute prior art to the present disclosure, and no part of this Discussion of the Background m section may be used as an admission that any part of this application, including this Discussion of the Background section, constitutes prior art to the present disclosure.

### SUMMARY

One aspect of the present disclosure provides a semiconductor device. The semiconductor device includes a wafer, a semiconductor chip, and a plurality of first reinforced structures. The semiconductor chip is disposed on the wafer and has a non-functional region and at least one functional region disposed in the non-functional region. The first reinforced structures penetrate through the semiconductor chip and into the wafer, and the first reinforced structures are located in the non-functional region.

In some embodiments, the first reinforced structures are solid rods.

In some embodiments, a top surface of each of the plurality of first reinforced structures is coplanar with an upper surface of the semiconductor chip.

In some embodiments, the semiconductor device further includes a plurality of second reinforced structures penetrate through the semiconductor chip and into the wafer, and the second reinforced structures are located in the non-functional region.

In some embodiments, the semiconductor chip has a plurality of functional regions, the first reinforced structures are disposed at corners of the semiconductor device, and the second reinforced structures are disposed between the functional regions.

In some embodiments, the second reinforced structures are m arranged in a honeycomb configuration.

In some embodiments, each of the plurality of second reinforced structures includes an upper electrode, a dielectric layer, and a lower electrode; the upper electrode penetrate through the semiconductor chip and into the wafer; the dielectric layer surrounds the upper electrode; and the lower electrode is disposed in the wafer and surrounds the dielectric layer.

Another aspect of the present disclosure provides a semiconductor device assembly. The semiconductor device assembly includes a wafer, a plurality of semiconductor chips, and a plurality of first reinforced structures. The semiconductor chips are disposed on the wafer and each of the plurality of semiconductor chips has a non-functional region and at least one functional region disposed in the non-functional region. The first reinforced structures penetrate through each of the plurality of semiconductor chips and into the wafer, and are located in the non-functional region.

In some embodiments, the first reinforced structures are solid rods.

In some embodiments, the semiconductor device assembly further includes a plurality of second reinforced structures penetrate through the semiconductor chip and into the wafer, and the second reinforced structures are located in the non-functional region.

In some embodiments, the second reinforced structures are decoupling capacitors.

In some embodiments, the semiconductor device assembly further includes a protective layer covering the semiconductor chips and the first reinforced structures.

Another aspect of the present disclosure provides a method for manufacturing a semiconductor device. The method includes steps of providing a wafer; providing a plurality of semiconductor chips on the wafer, wherein each of the plurality of semiconductor chips has a non-functional region and at least one functional region disposed in the non-functional region; forming a plurality of trenches in the non-functional region, wherein the plurality of trenches are formed through the semiconductor chips and into the wafer; and forming a plurality of first reinforced structures in the trenches.

In some embodiments, the step of disposing the plurality of first reinforced structures in the trenches includes a step of depositing a conductive material in the trenches.

In some embodiments, the method further includes a step of disposing a plurality of second reinforced structures in the trenches.

In some embodiments, the step of disposing the plurality of second reinforced structures in the trenches includes steps of forming lower electrodes in the wafer encircling the trenches; depositing a dielectric layer in the trenches; and depositing upper electrodes on the dielectric layer.

In some embodiments, the dielectric layer has a uniform thickness.

In some embodiments, the method further includes a step of depositing a protective layer on the semiconductor chips and the first reinforced structures.

In some embodiments, the method further includes a step of performing a grinding process to reduce the size of the wafer.

With the above-mentioned configurations of a semiconductor m device, the reinforced structures can effectively reinforce the strength of the semiconductor device and reduce the warpage of the wafer.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be coupled to the figures' reference numbers, which refer to similar elements throughout the description.

FIG. 1 is a flow diagram illustrating a method for manufacturing a semiconductor device assembly, in accordance with some embodiments of the present disclosure.

FIG. 2 illustrates a top view of an intermediate stage in the formation of a semiconductor device assembly in accordance with some embodiments of the present disclosure.

FIG. 3 is a close-up view of an area A of FIG. 2.

FIG. 4 is a cross-sectional view taken along the line I-I illustrated in FIG. 2.

FIG. 5 illustrates a cross-sectional view of an intermediate stage in the formation of the semiconductor device assembly in accordance with some embodiments of the present disclosure.

FIG. 6 is a schematic local top view of an intermediate stage in the formation of the semiconductor device assembly in accordance with some embodiments of the present disclosure.

FIGS. 7 through 10 illustrate cross-sectional views of intermediate stages in the formation of the semiconductor device assembly in accordance with some embodiments of the present disclosure.

FIG. 11 illustrates a cross-sectional view of a semiconductor device in accordance with some embodiments of the present disclosure.

FIG. 12 illustrates a top view of an intermediate stage in the formation of a semiconductor device assembly in accordance with some embodiments of the present disclosure.

FIG. 13 is a close-up view of an area B in FIG. 12.

FIGS. 14 and 15 illustrate cross-sectional views of intermediate stages in the formation of the semiconductor device assembly in accordance with some embodiments of the present disclosure.

FIG. 16 is a schematic local top view of an intermediate stage in the formation of the semiconductor device assembly in accordance with some embodiments of the present disclosure.

FIG. 17 is a cross-sectional view taken along the line II-II illustrated in FIG. 16.

FIG. 18 is a schematic local top view of an intermediate stage in the formation of the semiconductor device assembly in accordance with some embodiments of the present disclosure.

FIG. 19 is a cross-sectional view taken along the line III-III illustrated in FIG. 18.

FIGS. 20 and 21 illustrate cross-sectional views of intermediate stages in the formation of the semiconductor device assembly in accordance with some embodiments of the present disclosure.

FIG. 22 illustrates a cross-sectional view of a semiconductor device in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further application of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, m even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

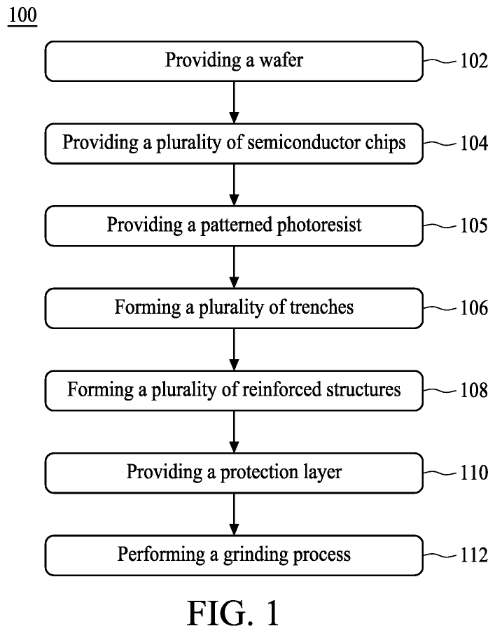

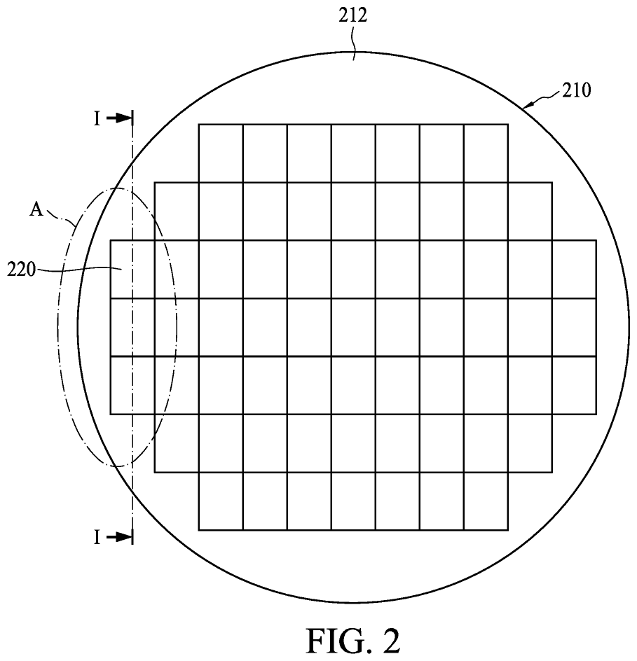

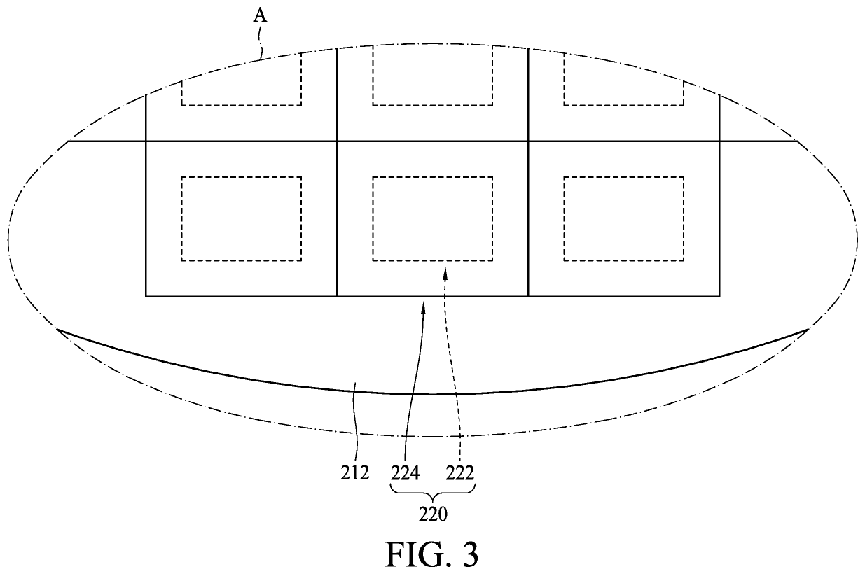

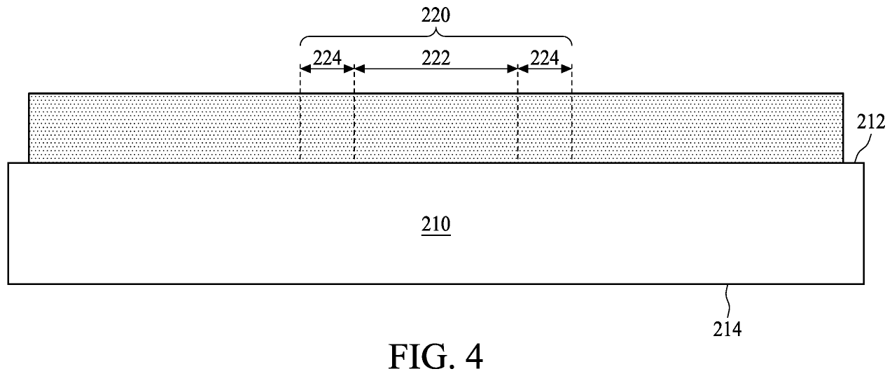

FIG. 1 is a flow diagram illustrating a method 100 for manufacturing a semiconductor device assembly 200, in accordance with some embodiments of the present disclosure. FIGS. 2 to 10 are schematic diagrams illustrating various fabrication stages constructed according to the method for manufacturing the semiconductor device assembly 200 in accordance with some embodiments of the present disclosure. The stages shown in FIGS. 2 through 10 are also illustrated schematically in the process flow in FIG. 1. In the subsequent discussion, the fabrication stages shown in FIGS. 2 through 10 are discussed in reference to the process steps in FIG. 1.

Referring to FIGS. 2 to 4, a wafer 210 is provided according to a step 102 in FIG. 1. In some embodiments, the wafer 210 is formed of a semiconductor, such as silicon. In some embodiments, the wafer 210 has a front surface 212 and a back surface 214 opposite to the front surface 212. In some embodiments, the front surface 212 and the back surface 214 are smooth and/or flat surfaces.

Next, a plurality of semiconductor chips 220 are provided on the wafer 210 according to a step 104 in FIG. 1. In some embodiments, the semiconductor chips 220 are disposed on the front surface 212 of the wafer 210. In some embodiments, the semiconductor chips 220 may be any functional chip such as a digital device chip formed by semiconductor process in advance. In some embodiments, the semiconductor chip 220 has a non-functional region 224 and a functional region 222 disposed in the non-functional region 224. In some embodiments, the functional region 222 and the non-functional region 224 are in an active area of the semiconductor chip 220.

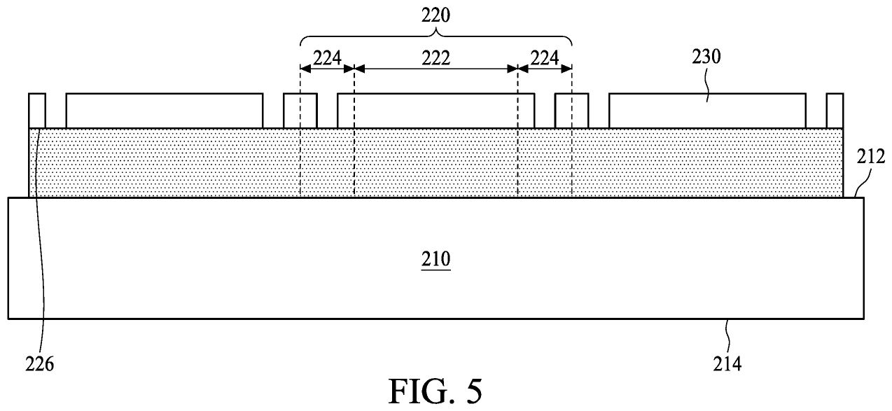

Referring to FIG. 5, a patterned photoresist 230 is provided over the semiconductor chips 220 according to a step 105 in FIG. 1. In some embodiments, the patterned photoresist 230 is formed by disposing an unpatterned photoresist layer to fully cover the semiconductor chips 220, then moving portions of the photoresist layer in accordance with a predefined pattern; the remaining portion of the photoresist layer forms the patterned photoresist 230. In some embodiments, the moved portions of the photoresist layer are in the non-functional region 224. In some embodiments, portions of upper surfaces 226 of the semiconductor chips 220, opposite to the front surface 212 of the wafer 210, are exposed to the patterned photoresist 230.

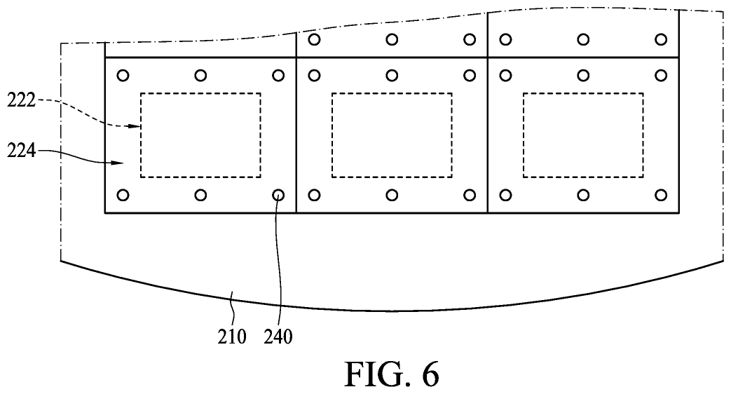

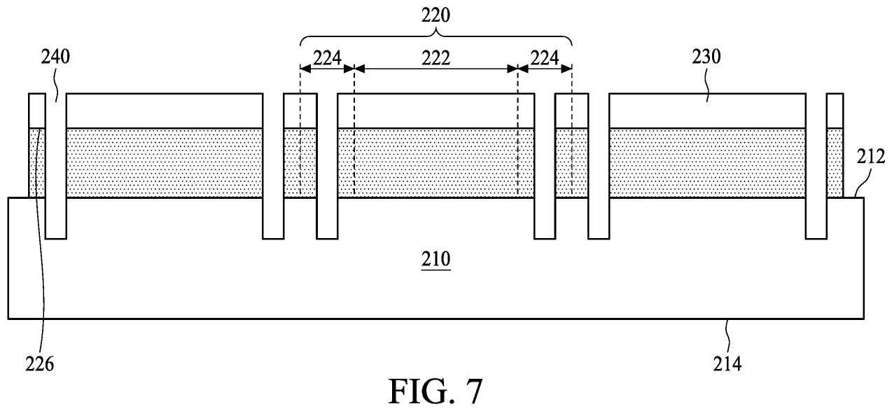

Referring to FIGS. 6 and 7, in some embodiments, an etching process is performed to form a plurality of trenches 240 in the non-functional region 224 according to a step 106 in FIG. 1. In some embodiments, the trenches 240 are formed through the semiconductor chips 220 and into the wafer 210. In some embodiments, the trench 240 has an approximately circular shape in a plan view. In some embodiments, the trenches 240 are evenly spaced from each other along a longitudinal direction of the semiconductor chip 220. In some embodiments, unnecessary portions of the semiconductor chips 220 and the wafer 210 are etched away using the patterned photoresist 230 as a mask. In some embodiments, the etching process uses the patterned photoresist 230 to define an area to be etched and to protect other regions of the semiconductor chips 220 and the wafer 210. In some embodiments, after the etching process is performed, the semiconductor chips 220 and the wafer 210 remain only in portions that are below the patterned photoresist 230. In some embodiments, the patterned photoresist 230 is removed after the forming of the trenches 240.

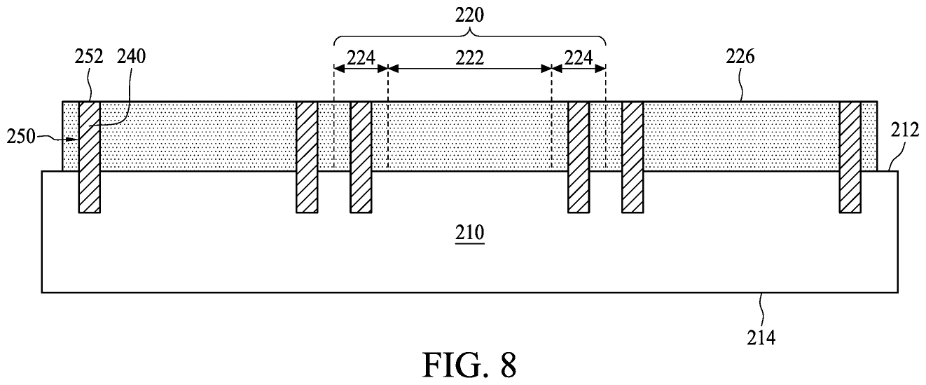

Referring to FIG. 8, a plurality of reinforced structures 250 are disposed in the trenches 240 according to a step 108 in FIG. 1. In some embodiments, the reinforced structures 250 are solid rods. In some embodiments, the reinforced structure 250 includes a conductive material. In some embodiments, the reinforced structure 250 includes copper. In some embodiments, the reinforced structures 250 are formed using an electrochemical plating process. In some embodiments, a planarizing process is optionally performed on the semiconductor chips 220 to remove excess portions of the conductive material over the upper surface 226, so that a top surface 252 of the reinforced structure 250 is coplanar with the upper surface 226. In some embodiments, the planarizing process includes a chemical mechanical polishing (CMP) process.

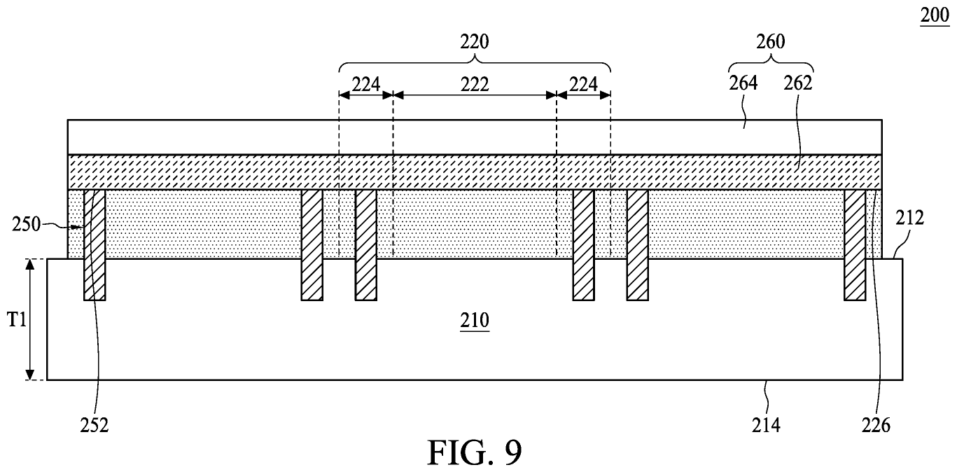

Referring to FIG. 9, an optional protective layer 260 is provided on the semiconductor chips 220 and the reinforced structures 250 according to a step 110 in FIG. 1. Accordingly, a semiconductor device assembly 200 is formed. In some embodiments, the protective layer 260 fully covers the upper surface 226 of the semiconductor chips 220 and the top surface 252 of the reinforced structures 250. In some embodiments, the protective layer 260 is a composite protective layer, comprised of an underlying layer 262 in contact with the upper surface 226 and the top surface 252, and an overlying layer 264 disposed on the underlying layer 262. In some embodiments, the underlying layer 262 includes nitride. In some embodiments, the underlying layer 262 includes silicon nitride. In some embodiments, the overlying layer 264 includes polyimide. In some embodiments, the protective layer 260 is used for protecting the semiconductor chips 220 (and the reinforced strictures 250) during a handling process.

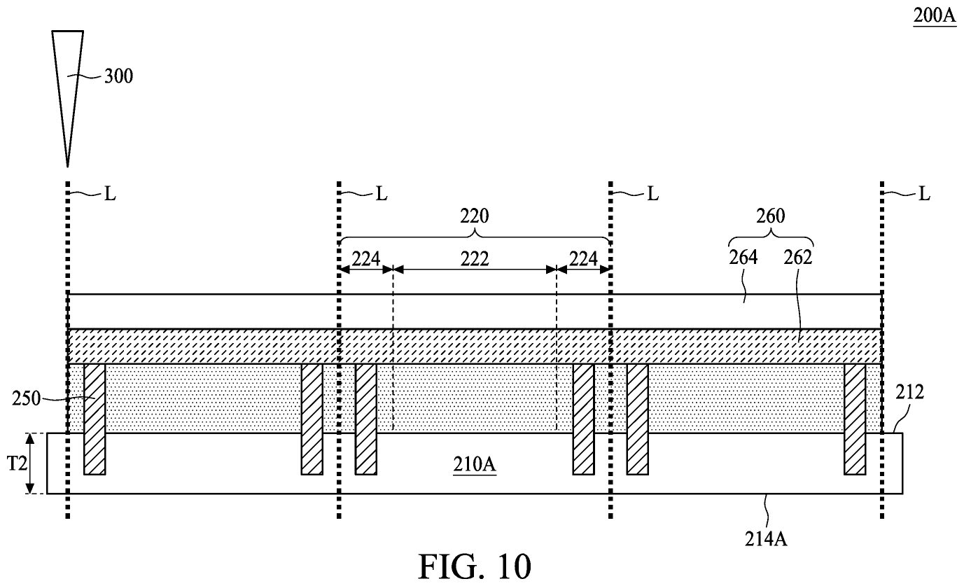

Referring to FIG. 10, a grinding process is performed to reduce the size of the wafer 210 according to a step 112 in FIG. 1. Accordingly, a ground semiconductor device assembly 200A is formed. In some embodiments, the grinding process is performed from the back surface 214 of the wafer 210. In some embodiments, the ground wafer 210A has a thickness T2, from the front surface 212 to a rear surface 214A thereof (as shown in FIG. 10), which is less than a thickness T1 of the wafer 210, from the front surface 212 to the back surface 214 thereof (as shown in FIG. 9). In some embodiments, the thickness T1 is substantially equal to 700 μm. In some embodiments, the thickness T2 is substantially less than 50 μm. In some embodiments, the thickness T2 is substantially equal to 35 μm.

In some embodiments, the semiconductor device assembly 200A includes a wafer 210A, a plurality of semiconductor chips 220, a plurality of reinforced structures 250, and a protective layer 260. In some embodiments, the semiconductor chips 220 are disposed on a front surface 212 of the wafer 210A, and each of the semiconductor chips 220 has a non-functional region 224 and a functional region 222 disposed in the non-functional region 224. In some embodiments, the reinforced structures 250 penetrate through the semiconductor chip 220 and into the wafer 210A. In some embodiments, the reinforced structures 250 are located in the non-functional region 224. In some embodiments, the protective layer 260 covers the semiconductor chips 220 and the reinforced structures 250 and is comprised of an underlying layer 262 of nitride and an overlying layer 264 of polyimide. In some embodiments, the semiconductor device assembly 200A may include one or more through silicon vias in each of the functional regions, and each of the through silicon vias penetrates through the corresponding semiconductor chip 220 and into the wafer 210A.

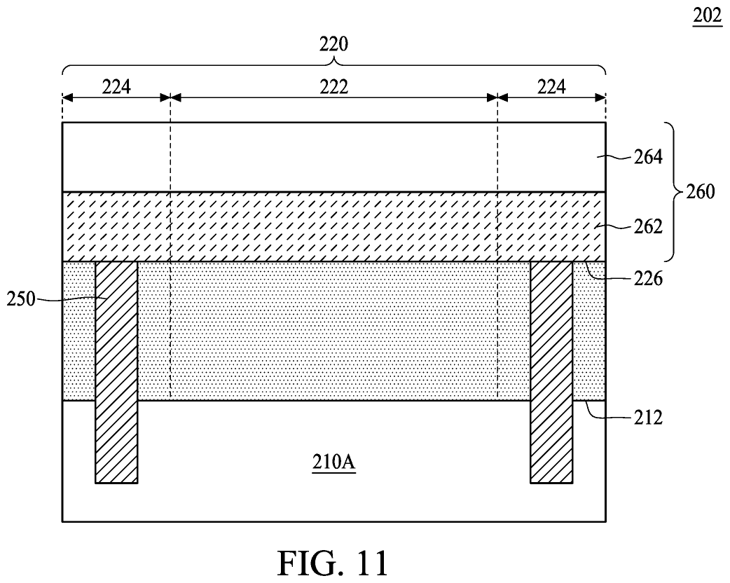

In some embodiments, the semiconductor device assembly 200A may be sawed apart into a plurality of semiconductor devices 202 shown in FIG. 11. In some embodiments, the sawing process is performed using a saw blade 300, as shown in FIG. 10. In some embodiments, the sawing is aligned with sawing lines L shown in FIG. 10. In some embodiments, each of the semiconductor devices 202 includes one of the semiconductor chips 220 and the corresponding wafer 210A, reinforced structures 250, and protective layer 260. In some embodiments, the reinforced structures 250 located in the non-functional region 224 are used for preventing the wafer 210A of the semiconductor device 202 from deforming (i.e., warping) after the grinding process and the sawing process.

Referring to FIG. 11, in some embodiments, the semiconductor device 202 includes a wafer 210A, a semiconductor chip 220 disposed on a front surface 212 of the wafer 210A, and a plurality of reinforced structures 250 penetrate through the semiconductor chip 220 and into the wafer 210A; and a protective layer 260 covers the semiconductor chip 220 and the reinforced structures 250. In some embodiments, the reinforced structures 250 are located in a non-functional region 224 of the semiconductor chip 220. In some embodiments, the reinforced structures 250 can effectively reinforce the strength of the semiconductor device 202 and reduce the warpage of the wafer 210A of the semiconductor device 202.

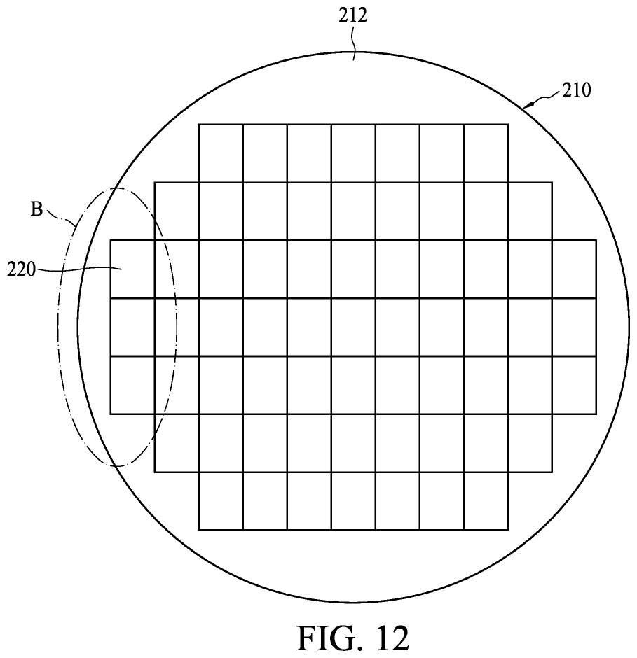

FIGS. 12 to 21 are schematic diagrams illustrating various fabrication stages constructed according to the method for manufacturing a semiconductor device assembly 200 in accordance with some embodiments of the present disclosure. The stages shown in FIGS. 12 through 21 are also illustrated schematically in the process flow in FIG. 1. In the subsequent discussion, the fabrication stages shown in FIGS. 12 through 21 are discussed in reference to the process steps in FIG. 1.

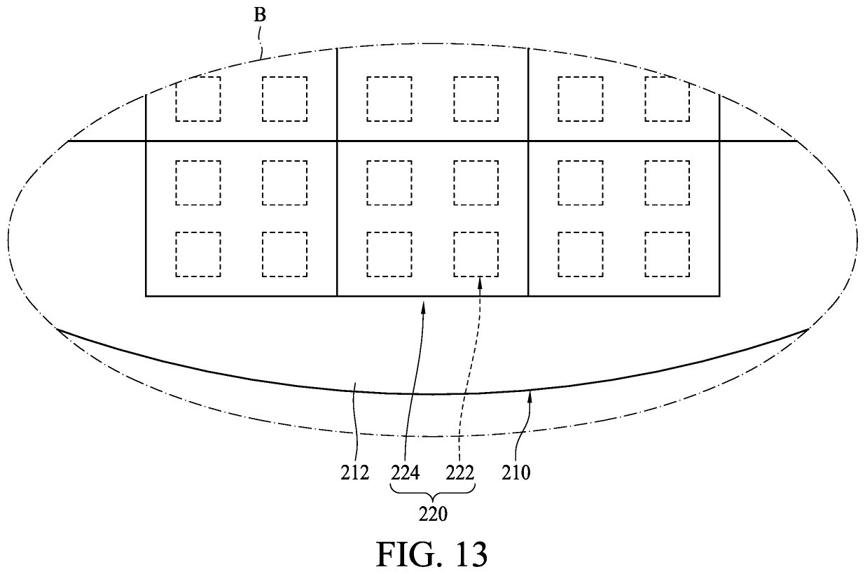

Referring to FIGS. 12 and 13, in some embodiments, a wafer 210 is provided according to a step 102 in FIG. 1. In some embodiments, the wafer 210 is a bulk silicon wafer. Next, a plurality of semiconductor chips 220 are provided according to a step 104 in FIG. 1. In some embodiments, the semiconductor chips 220 are disposed on a front surface 212 of the wafer 210. In some embodiments, the semiconductor chip 220 has a non-functional region 224 and a plurality of functional regions 222 disposed in the non-functional region 224. In some embodiments, the functional areas 222 and the non-functional area 224 are in an active area of the semiconductor chip 220. In some embodiments, the semiconductor chips 220 may be a memory chip or any functional chip formed by semiconductor process in advance. In some embodiments, when the semiconductor chip 220 is a memory chip, the non-functional region 224 is a region where memory cells are not disposed.

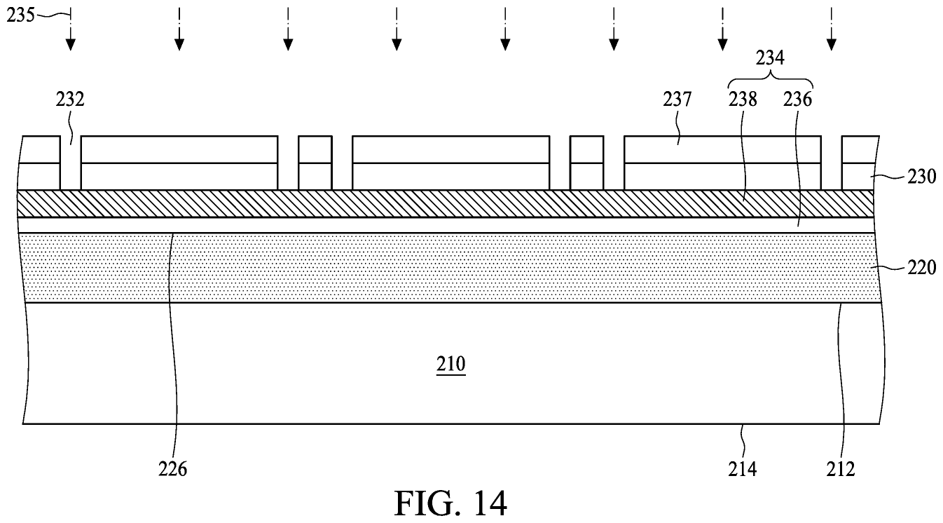

Referring to FIG. 14, in some embodiments, a dielectric layer 234 is deposited on upper surfaces 226 of the semiconductor chips 220. In some embodiments, the dielectric layer 234 is a composite dielectric layer, comprised of a first layer 236 of oxide and a second layer 238 of nitride. In some embodiments, the first layer 236 is disposed between the upper surfaces 226 and the second layer 238. In some embodiments, the first layer 236 includes silicon dioxide, and the second layer 238 includes silicon nitride.

Next, a patterned photoresist 230 is provided on the second layer 238 according to a step 105 in FIG. 1. In some embodiments, the patterned photoresist 230 is provided by steps including (1) providing a photoresist layer on the second layer 238, and (2) forming openings 232 in the photoresist layer by exposing the photoresist layer to actinic radiation 235 through a patterned photomask 237 and developing away either the exposed or unexposed regions of the photoresist layer. In some embodiments, the openings 232 are located in the non-functional region 224.

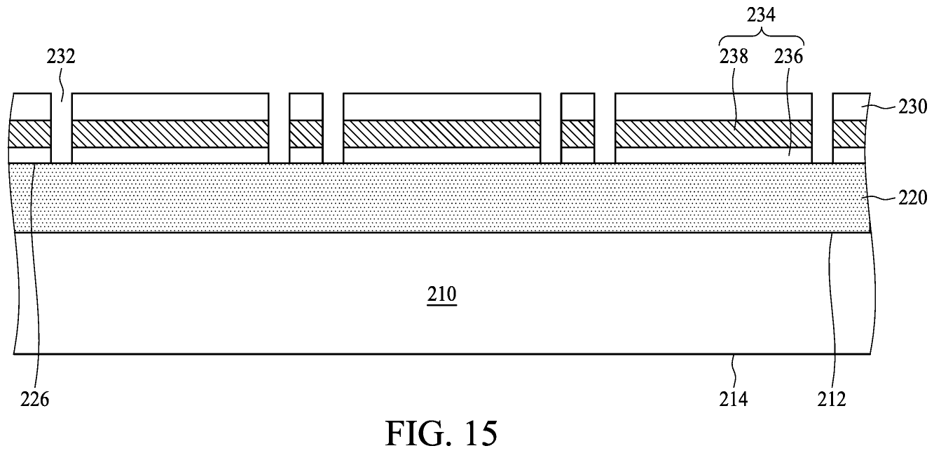

Referring to FIG. 15, an etching process, for example, a reactive ion etch (RIE) process, is performed to remove portions of the first layer 236 and second layer 238. In some embodiments, unnecessary portions of the first layer 236 and the second layer 238 are etched away using the patterned photoresist 230 as a mask. In some embodiments, portions of the upper surfaces 226 are exposed to the first layer 236 and the second layer 238.

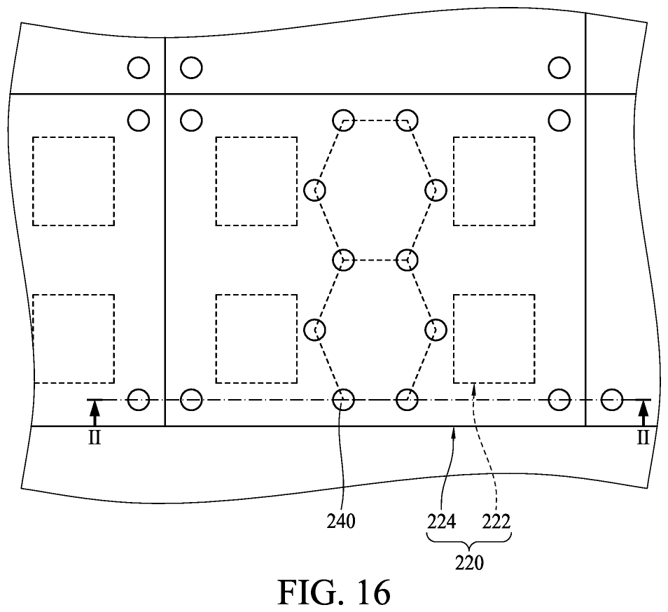

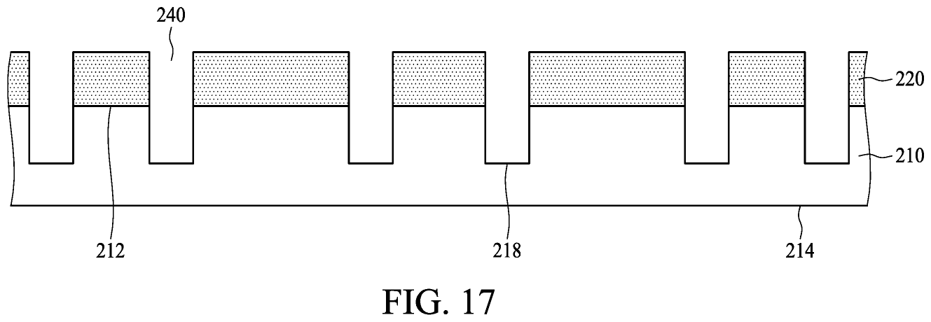

Referring to FIGS. 16 and 17, in some embodiments, a plurality of trenches 240 are etched through the semiconductor chips 220 and into the wafer 210 according to a step 106 in FIG. 1. In some embodiments, the trenches 240 are located in the non-functional region 224. In some embodiments, the trench 240 has an approximately circular shape in a plan view. In some embodiments, some of the trenches 240 are formed at corners of the semiconductor chip 220. In some embodiments, the trenches 240 between the functional regions 222 are arranged in a honeycomb configuration. In some embodiments, the trenches 240 are formed using a photolithographic/etching process. In some embodiments, the photolithographic/etching process includes (1) removing the patterned photoresist layer 230, and (2) etching the semiconductor chips 220 and the wafer 210 using, for example, an RIE process using the pattern in the first layer 236 and second layer 238 as a hardmask. In some embodiments, the first layer 236 and the second layer 238 are then removed using, for example, wet etching processes.

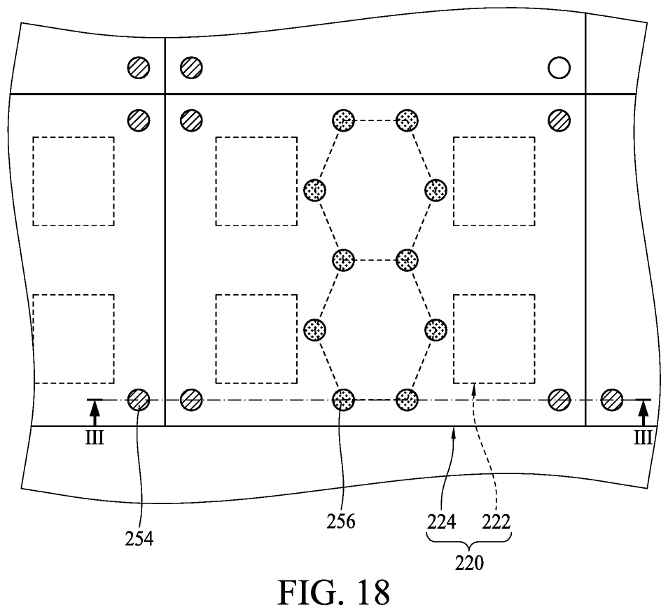

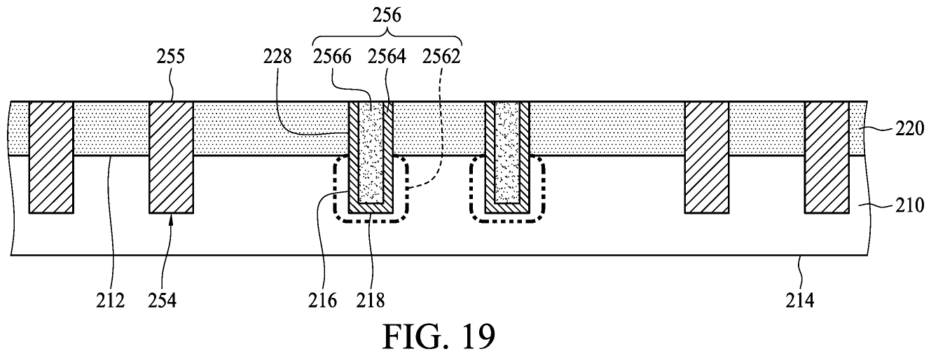

Referring to FIGS. 18 and 19, a plurality of first reinforced structures 254 and a plurality of second reinforced structures 256 are formed in the trenches 240 according to a step 108 in FIG. 1. In some embodiments, the first reinforced structures 254 are disposed at the corners of the semiconductor chip 220, and the second reinforced structures 256 are disposed between the functional regions 222. In some embodiments, the first reinforced structures 254 are solid rods. In some embodiments, the first reinforced structures 254 include a conductive material. In some embodiments, the first reinforced structures 254 include copper. In some embodiments, a top surface 255 of the first reinforced structure 254 is coplanar with the upper surface 226.

In some embodiments, the second reinforced structures 256 are deep trench capacitors. In some embodiments, the second reinforced structures 256 are decoupling capacitors. In some embodiments, the second reinforced structure 256 is formed by steps including (1) forming a lower electrode 2562 in the wafer 210 and surrounding the trench 240, (2) depositing a dielectric layer 2564, such as oxide-nitride-oxide (ONO) layer, on a first wall 216 and a second wall 218 of the wafer 210 and a sidewall 228 of the semiconductor chip 220, and depositing an upper electrode 2566 on the dielectric layer 2564. In some embodiments, the lower electrode 2562 is a doped region in the wafer 210. In some embodiments, the upper electrode 2566 is formed by a conductive material, for example, doped polysilicon. In some embodiments, the first wall 216 is continuous with the sidewall 228, and the second wall 218 is substantially parallel to the front surface 212. In some embodiments, the dielectric layer 2564 has a uniform thickness.

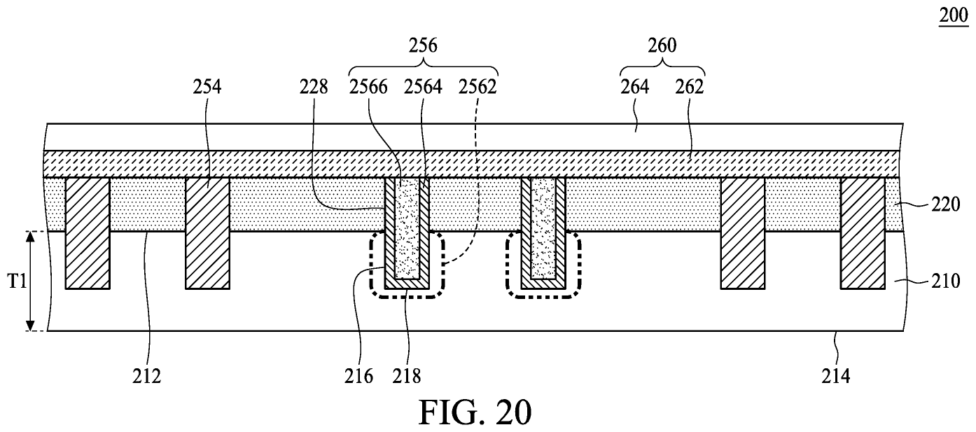

Referring to FIG. 20, an optional protective layer 260 is provided on the semiconductor chip 220, the first reinforced structure 254, and the second reinforced structure 256 according to a step 110 in FIG. 1. Accordingly, a semiconductor device assembly 200 is formed. In some embodiments, the protective layer 260 is a composite protective layer, comprised of an underlying layer 262 of nitride and an overlying layer 264 of polyimide. In some embodiments, the underlying layer 262 is in contact with the semiconductor chip 220, the first reinforced structure 254, and the second reinforced structure 256, and the overlying layer 264 is disposed on the underlying layer 262. In some embodiments, the protective layer 260 is used for protecting the semiconductor chip 220, the first reinforced structure 254, and the second reinforced structure 256 during a handling process.

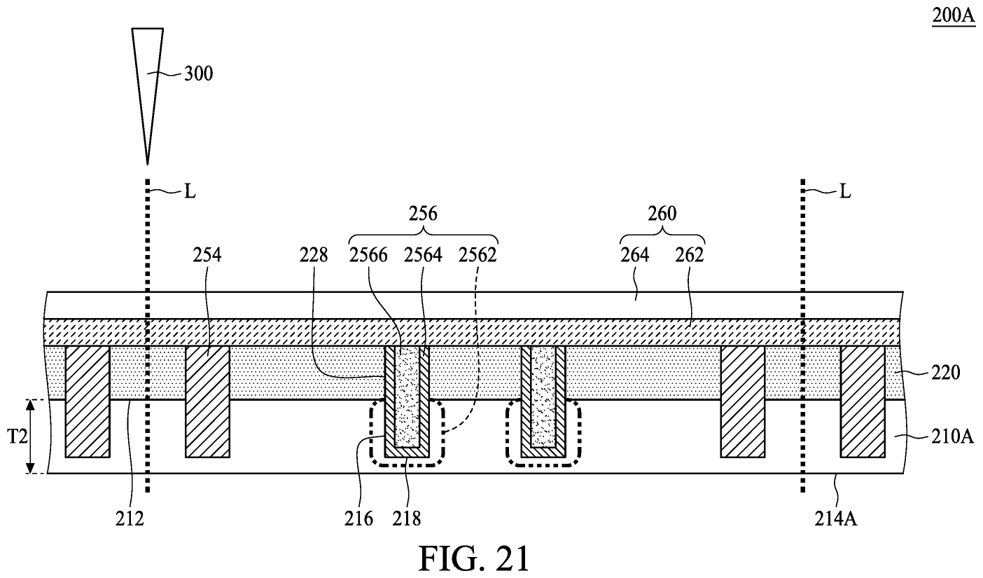

Referring to FIG. 21, a grinding process is performed to reduce the size of the wafer 210 according to a step 112 in FIG. 1. Accordingly, a ground semiconductor device assembly 200A is formed. In some embodiments, the grinding process is performed from the back surface 214 of the wafer 210. In some embodiments, the ground wafer 210A has a thickness T2 shown in FIG. 21, from the front surface 212 to a rear surface 214A thereof, which is less than a thickness T1 of the wafer 210, from the front surface 212 to the back surface 214 thereof (as shown in FIG. 20). In some embodiments, the thickness T1 is substantially equal to 700 μm. In some embodiments, the thickness T2 is substantially less than 50 μm.

In some embodiments, the semiconductor device assembly 200A includes a wafer 210A, a plurality of semiconductor chips 220, a plurality of first reinforced structures 254, a plurality of second reinforced structures 256, and a protective layer 260. In some embodiments, the semiconductor chips 220 are disposed on a front surface 212 of the wafer 210A, and each of the semiconductor chips 220 has a non-functional region 224 and a plurality of functional regions 222 disposed in the non-functional region 224. In some embodiments, the first reinforced structures 254 and the second reinforced structures 256 penetrate through the semiconductor chip 220 and into the wafer 210A. In some embodiments, the first reinforced structures 254 and the second reinforced structures 256 are located in the non-functional region 224. In some embodiments, the protective layer 260 covers the semiconductor chips 220, the first reinforced structures 254, and the second reinforced structures 256, and is comprised of an underlying layer 262 of nitride and an overlying layer 264 of polyimide.

In some embodiments, the first reinforced structures 254 are solid rods. In some embodiments, the second reinforced structure 256 includes an upper electrode 2566 penetrating through the semiconductor chip 220 and into the wafer 210A, a dielectric layer 2564 surrounding the upper electrode 2566, and a lower electrode 2562 disposed in the wafer 210A and surrounding the dielectric layer 2564. In some embodiments, the lower electrode 2562 is a doped region in the wafer 210A. In some embodiments, the semiconductor device assembly 200A may include one or more through silicon vias in each of the functional regions, wherein each of the through silicon vias penetrate through the corresponding semiconductor chip 220 and into the wafer 210A.

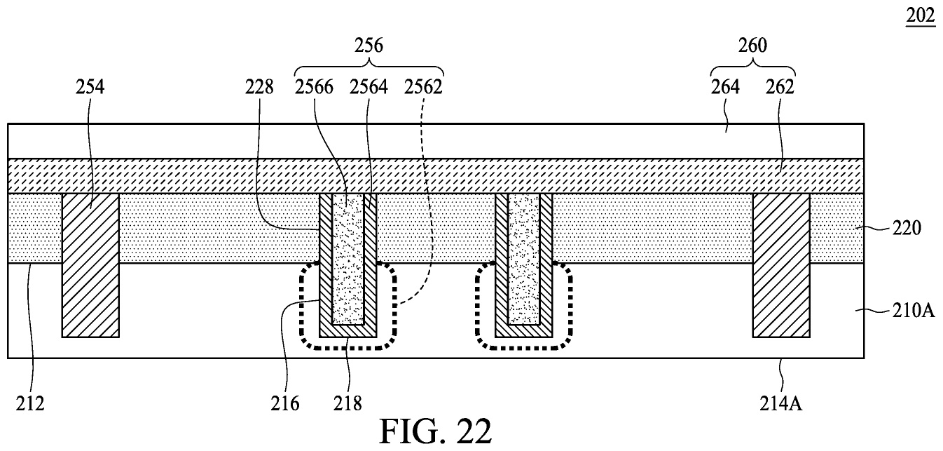

In some embodiments, the semiconductor device assembly 200A may be sawed apart into a plurality of semiconductor devices 202 as shown in FIG. 22. In some embodiments, the sawing process is performed, as shown in FIG. 21, using a saw blade 300. In some embodiments, the sawing is aligned with sawing lines L as shown in FIG. 21. In some embodiments, each of the semiconductor devices 202 includes one of the semiconductor chips 220 and the corresponding wafer 210A, as well as the first reinforced structures 254, the second reinforced structures 256, and the protective layer 260. In some embodiments, the first reinforced structures 254 and the second reinforced structures 256 located in the non-functional region 224 are used for preventing the wafer 210A of the semiconductor device 202 from deforming (i.e., warping) during the grinding process or the sawing process. In some embodiments, the second reinforced structures 256, serving as charge reservoirs, are used to support instantaneous current surges and prevent noise-related circuit degradation in the semiconductor device 202.

In conclusion, with the configuration of the semiconductor device 202, the reinforced structures 250/254 (and the second structures 256) can effectively reinforce the strength of the semiconductor device 202 and reduce the warpage of the wafer 210A.

One aspect of the present disclosure provides a semiconductor device. The semiconductor device includes a wafer, a semiconductor chip, and a plurality of first reinforced structures. The semiconductor chip is disposed on the wafer and has a non-functional region and at least one functional region disposed in the non-functional region. The first reinforced structures penetrate through the semiconductor chip and into the wafer, and the first reinforced structures are located in the non-functional region.

One aspect of the present disclosure provides a semiconductor m device assembly. The semiconductor device assembly includes a wafer, a plurality of semiconductor chips, and a plurality of first reinforced structures. The semiconductor chips are disposed on the wafer and each of the plurality of semiconductor chips has a non-functional region and at least one functional region disposed in the non-functional region. The first reinforced structures penetrate through each of the plurality of semiconductor chips and into the wafer, and are located in the non-functional region.

One aspect of the present disclosure provides a method for manufacturing a semiconductor device. The method includes steps of providing a wafer; providing a plurality of semiconductor chips on the wafer, wherein each of the plurality of semiconductor chips has a non-functional region and at least one functional region disposed in the non-functional region; forming a plurality of trenches in the non-functional region, wherein the plurality of trenches are formed through the semiconductor chips and into the wafer; and forming a plurality of first reinforced structures in the trenches.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps m described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor device, comprising:
a wafer;
a semiconductor chip disposed on the wafer, wherein the semiconductor chip has a non-functional region and at least one functional region disposed in the non-functional region; and
a plurality of first reinforced structures penetrating through the semiconductor chip and into the wafer, and located in the non-functional region.

2. The semiconductor device of claim 1, wherein the first reinforced structures are solid rods.

3. The semiconductor device of claim 2, wherein a top surface of each of the plurality of first reinforced structures is coplanar with an upper surface of the semiconductor chip.

4. The semiconductor device of claim 1, further comprising a plurality of second reinforced structures penetrating through the semiconductor chip and into the wafer, and located in the non-functional region.

5. The semiconductor device of claim 4, wherein the semiconductor chip has a plurality of functional regions, the first reinforced structures are disposed at corners of the semiconductor device, and the second reinforced structures are disposed between the functional regions.

6. The semiconductor device of claim 5, wherein the second reinforced structures are arranged in a honeycomb configuration.

7. The semiconductor device of claim 4, wherein the second reinforced structures are decoupling capacitors.

8. A semiconductor device assembly, comprising:
a wafer;
a plurality of semiconductor chips disposed on the wafer, wherein each of the plurality of semiconductor chips has a non-functional region and at least one functional region disposed in the non-functional region; and
a plurality of first reinforced structures penetrating through each of the plurality of semiconductor chips and into the wafer, and located in the non-functional region.

9. The semiconductor device assembly of claim 8, wherein the first reinforced structures are solid rods.

10. The semiconductor device assembly of claim 8, further comprising a plurality of second reinforced structures penetrating through the semiconductor chip and into the wafer, and located in the non-functional region.

11. The semiconductor device assembly of claim 10, wherein each of the plurality of second reinforced structures comprises:
an upper electrode penetrating through the semiconductor chip and into the wafer;
a dielectric layer surrounding the upper electrode; and
a lower electrode disposed in the wafer and surrounding the dielectric layer.

12. The semiconductor device assembly of claim 11, wherein the lower electrode is a doped region.

13. The semiconductor device assembly of claim 8, further comprising a protective layer covering the semiconductor chips and the first reinforced structures.

14. A method for manufacturing a semiconductor device assembly, comprising:
providing a wafer;
providing a plurality of semiconductor chips on the wafer, wherein each of the plurality of semiconductor chips has a non-functional region and at least one functional region disposed in the non-functional region;
forming a plurality of trenches in the non-functional region, wherein the plurality of trenches are formed through the semiconductor chips and into the wafer; and
forming a plurality of first reinforced structures in the trenches.

15. The method of claim 14, wherein the step of disposing the plurality of first reinforced structures in the trenches comprises:
depositing a conductive material in the trenches.

16. The method of claim 14, further comprising:
disposing a plurality of second reinforced structures in the trenches.

17. The method of claim 16, wherein the step of disposing the plurality of second reinforced structures in the trenches comprises:
forming lower electrodes in the wafer encircling the trenches;
depositing a dielectric layer in the trenches; and
depositing upper electrodes on the dielectric layer.

18. The method of claim 17, wherein the dielectric layer has a uniform thickness.

19. The method of claim 14, further comprising:
depositing a protective layer on the semiconductor chips and the first reinforced structures.

20. The method of claim 14, further comprising performing a grinding process to reduce the size of the wafer.
